(19) United States
(12) Patent Application Publication
(10) Pub. No.: US 2012/0211060 A1
(43) Pub. Date: Aug. 23, 2012

(54) THIN-FILM SOLAR CELL MODULE AND METHOD FOR MANUFACTURING THE SAME

(76) Inventors: Jinhyung AHN, Seoul (KR); Sungeun LEE, Seoul (KR); Jeonghun SON, Seoul (KR)

(21) Appl. No.: 13/401,281

(22) Filed: Feb. 21, 2012

(30) Foreign Application Priority Data
Feb. 22, 2011 (KR) 10-2011-0015707

(51) Int. Cl. H01L 31/048; H01L 31/18; H01L 31/05

(52) U.S. Cl. 136/251; 136/244; 438/66; 257/E31.124

(57) ABSTRACT

A thin-film solar cell module includes a plurality of solar cells including a first solar cell that is an outermost solar cell. The first electrode of the first solar cell is electrically open, and the first electrode of the first solar cell has a width smaller than widths of the first electrodes of the plurality of solar cells other than the first solar cell. By reducing a width of the outermost solar cell (that is a dead cell), the conversion efficiency of the thin-film solar cell module may be enhanced.

### CROSS-REFERENCE TO RELATED APPLICATION

This application claims the priority benefit of Korean Patent Application No. 10-2011-0015707, filed on Feb. 22, 2011 in the Korean Intellectual Property Office, the disclosure of which is incorporated herein by reference.

### BACKGROUND

1. Field of the Disclosure

The present disclosure relates to a thin-film solar cell and a method for manufacturing the same, and more particularly, to a thin-film solar cell having enhanced efficiency and a method for manufacturing the same.

2. Description of the Related Art

Recently, as existing energy resources such as oil or coal are expected to be exhausted, an interest in alternative energy for replacing oil or coal is increasing. In particular, a solar cell that directly converts or transforms solar energy into electricity using a semiconductor element is gaining attention.

A solar cell uses a p-n junction. Various materials (for example, a mono-crystalline silicon solar cell, a multi-crystalline silicon solar cell, an amorphous silicon solar cell, a compound solar cell, a dye-sensitized solar cell, and the like) are used for a solar cell in order to improve efficiency and properties. In the commonly utilized crystalline silicon solar cell, its material unit cost is high compared with generating efficiency, and its process is complicated. Thus, in order to overcome this, an interest in a thin-film solar cell in which the price is low is on the rise.

In the thin-film solar cell, an electrode layer and a silicon layer are thinly deposited on a surface of glass or plastic. Then, the deposited silicon layer is separated to correspond to a plurality of solar cells by a scribing process, and a lower electrode of a first solar cell and an upper electrode of a second solar cell adjacent to the first solar cell are connected. Thus, the plurality of solar cells are connected to each other in series.

However, the lower electrode of the outermost solar cell among the plurality of solar cells is not electrically connected to the upper electrode of the other solar cells, and thus, the outermost solar cell becomes a dead cell that cannot generate electricity. Therefore, output of the thin-film solar cell may be reduced.

### SUMMARY

The present disclosure discloses a thin-film solar cell having enhanced conversion efficiency and a method for manufacturing the same.

A thin-film solar cell module according to one embodiment includes a transparent substrate; and a plurality of solar cells formed on the transparent substrate. The plurality of solar cells are in parallel to each other and are connected to each other in series. Each of the plurality of solar cells includes a first electrode on the transparent substrate, a photoelectric conversion layer on the first electrode, and the second electrode on the photoelectric conversion layer. The plurality of solar cells include a first solar cell that is an outermost solar cell. The first electrode of the first solar cell is electrically open, and the first electrode of the first solar cell has a width smaller than widths of the first electrodes of the plurality of solar cells other than the first solar cell.

The first solar cell may have a width smaller than widths of the plurality of solar cells other than the first solar cell.

The plurality of solar cells other than the first solar cell may have substantially same widths with respect to each other.

The thin-film solar cell module may further include a first electrode terminal on the first solar cell and a second electrode terminal on an other outermost solar cell among the plurality of solar cells. The first solar cell may have the width larger than a width of the first electrode terminal by about 0.1˜4 mm.

The plurality of solar cells may include a second solar cell that is adjacent to the first solar cell. The first electrode of the first solar cell may be separated from the first electrode of the second solar cell by a first groove, and the photoelectric conversion layer of the first solar cell may be separated from the photoelectric conversion layer of the second solar cell by a second groove. Here, the first groove and the second groove may partially overlap with each other.

The thin-film solar cell module may further include a sealing layer for sealing the plurality of solar cells.

The plurality of solar cells may include a second solar cell that is adjacent to the first solar cell, and the second electrode of the first solar cell may be connected to the first electrode of the second solar cell.

On the other hand, a method for manufacturing a thin-film solar cell module includes steps of: forming first electrodes spaced from each other by depositing a conductive layer on a transparent substrate and patterning the conductive layer; forming photoelectric conversion layers spaced from each other by depositing a silicon thin-film layer on the first electrodes and patterning the silicon thin-film layer; and forming plurality of solar cells by depositing an electrode layer on the photoelectric conversion layers and patterning the electrode layer to form second electrodes, wherein the plurality of solar cells are arranged in parallel with each other, each of the plurality of solar cells including the first electrode, the second electrode, and the photoelectric conversion layer. The plurality of solar cells include a first solar cell that is an outermost solar cell. The first electrode of the first solar cell is electrically open, and the first electrode of the first solar cell has a width smaller than widths of the first electrodes of the plurality of solar cells other than the first solar cell.

The first solar cell may have a width smaller than widths of the plurality of solar cells other than the first solar cell.

The plurality of solar cells may include a second solar cell that is adjacent to the first solar cell. The method may further include a step of forming a first electrode terminal on the first solar cell and a second electrode terminal on an other outermost solar cell among the plurality of solar cells.

The first solar cell may have the width larger than a width of the first electrode terminal by about 0.1˜4 mm.

The plurality of solar cells may include a second solar cell that is adjacent to the first solar cell, and the first electrode of the first solar cell may be connected to the first electrode of the second solar cell.

The plurality of solar cells may include a second solar cell that is adjacent to the first solar cell. In the step of forming the first electrodes, first grooves may be formed through a first scribing process to separate the first electrodes. In the step of forming the photoelectric conversion layers, second groove may be formed through a second scribing process to separate the photoelectric conversion layers. One first groove of the first grooves between the first electrodes of the first solar cell and the second solar cell may partially overlap one second groove of the second grooves between the photoelectric conversion layers of the first solar cell and the second solar cell.

The method may further include a step of forming a sealing layer for sealing the plurality of solar cells.

### BRIEF DESCRIPTION OF THE DRAWINGS

FIG. 1 is a plan view illustrating a thin-film solar cell module according to an embodiment of the present invention.

FIG. 2 is a cross-sectional view illustrating the thin-film solar cell module shown in FIG. 1, taken along line A-A′.

FIGS. 3(a) and 3(b) are expanded views illustrating portion S of FIG. 2. FIGS. 4 to 8 are cross-sectional views illustrating a method for manufacturing a thin-film solar cell module according to an embodiment of the present invention.

### DETAILED DESCRIPTION OF THE PREFERRED EMBODIMENTS

It will be understood that when an element is referred to as being “on” or “under” another element, it can be directly on or under the other element, or intervening elements may be present. In addition, a top or a bottom of each constituent element may be described based on a top or a bottom of the drawings. Furthermore, the dimensions of layers and regions may be exaggerated or schematically illustrated, or some layers are omitted for clarity of illustration. In addition, the dimension of each part as drawn may not reflect an actual size.

Hereinafter, embodiments of the present invention will be described with reference to the accompanying drawings.

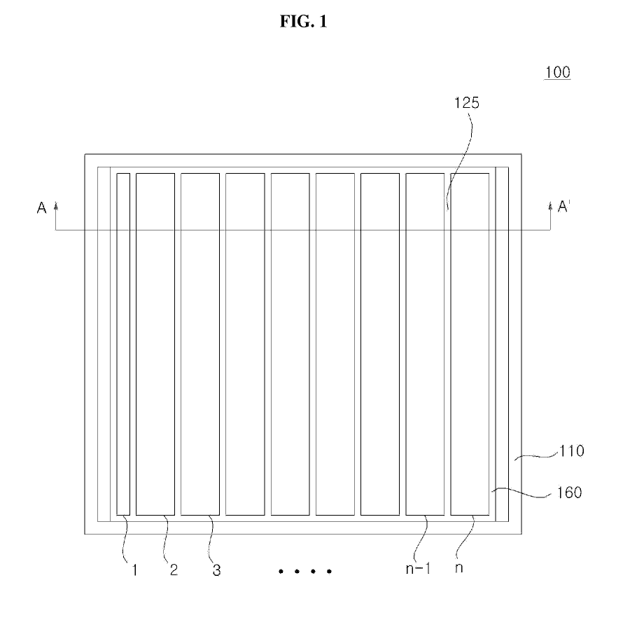

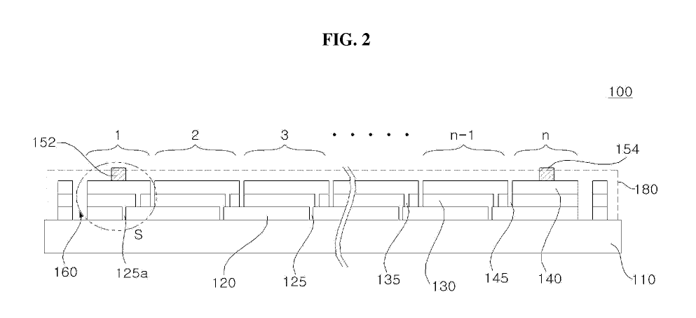

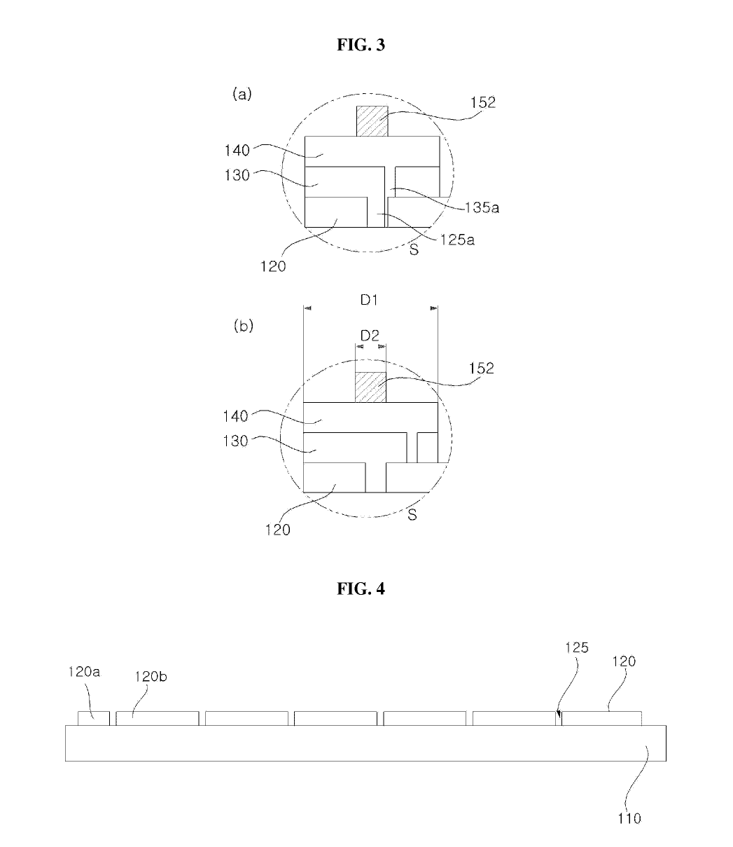

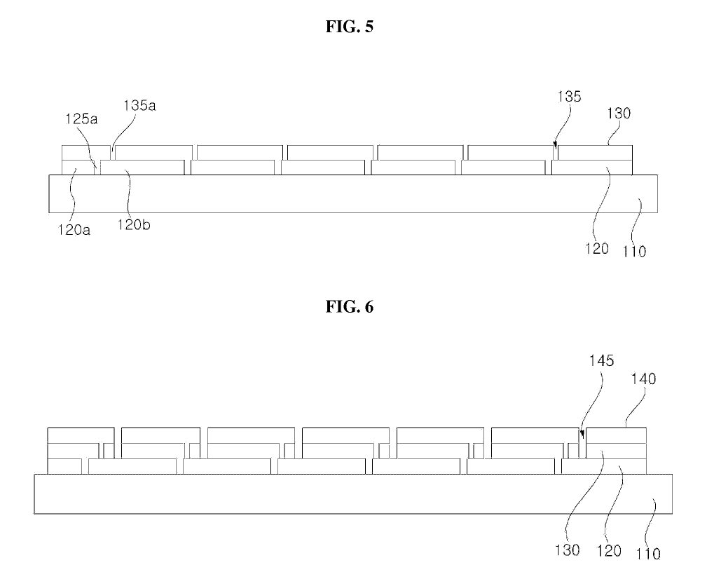

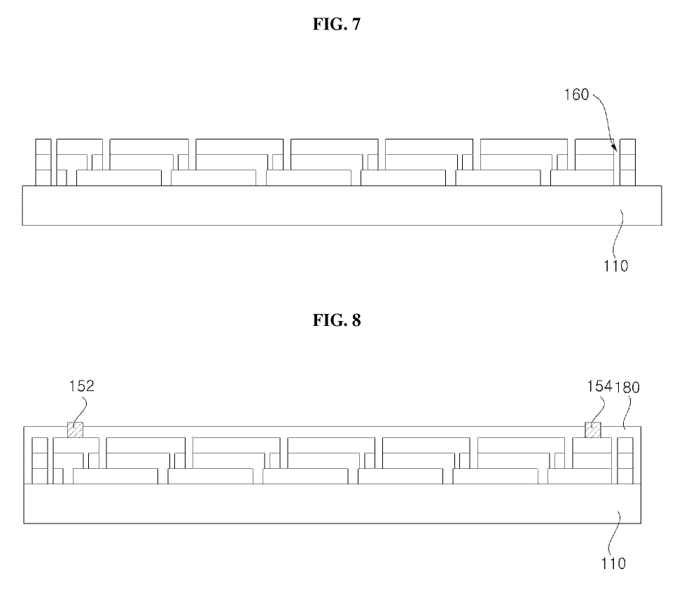

FIG. 1 is a plan view illustrating a thin-film solar cell module according to an embodiment of the present invention, and FIG. 2 is a cross-sectional view illustrating the thin-film solar cell module shown in FIG. 1, taken along line A-A′. FIGS. 3(a) and 3(b) are expanded views illustrating portion S of FIG. 2. In addition, FIG. 1 illustrates a front surface of a thin-film solar cell module 100. In the cross-section of FIG. 2, the front surface of the thin-film solar cell module 100 is the lower surface.

Referring to FIGS. 1 and 2, the thin-film solar cell module 100 according to the embodiment of the present invention may include a transparent substrate, and a plurality of solar cells (1˜n). The plurality of solar cells (1˜n) are formed on the substrate 110 to be in parallel to each other, and are connected to each other in series.

The substrate 110 may include glass or polymer that allows solar light to be transmitted therethrough.

The plurality of solar cells (1˜n) are formed on the substrate 110 to be in parallel to each other. Each of the plurality of solar cells (1˜n) may include a first electrode 120 on the substrate 110, a photoelectric conversion layer 130 on the first electrode 120, and the second electrode 140 on the photoelectric conversion layer 130.

The first electrode 120 may include a metal oxide having transparency and conductivity. For example, the first electrode 120 may be formed of one material selected from the group including tin oxide (SnO₂), zinc oxide (ZnO), and indium tin oxide (ITO), or a metal oxide including at least one impurity.

The first electrodes 120 are separated from each other by first grooves 125. The photoelectric conversion layer 130 is formed on the first electrode 120. The first electrode 120 of one solar cell is electrically connected to the second electrode 140 on the photoelectric conversion layer 130 of another solar cell adjacent to the above one solar cell.

Two solar cells (1, n) among the plurality of solar cells (1˜n) are the outermost cells. Here, the first electrode 120 of one solar cell between the two solar cells (1, n) is not electrically connected to the second electrode 140 on the photoelectric conversion layer 130 of another solar cell adjacent to the above one solar cell. Thus, the first electrode 120 of the above one solar cell between the two solar cells (1, n) forms an open circuit. In other words, one of a plus (+) terminal and a minus (−) terminal is not connected to the first electrode 120 of the above one solar cell between the two solar cells (1, n).

That is, as shown in FIG. 2, when the second electrode 140 of a first solar cell 1 that is the leftmost solar cell is connected to the first electrode 120 of a second solar cell 2 adjacent to the first solar cell 1, the first electrode 120 of the first solar cell 1 is not connected to the second electrodes 140 of the other solar cells (2˜n) and is in an electrically open state. Contrary to that shown in FIG. 2, when the first electrode 120 of the first solar cell 1 is connected to the second electrode 120 of the second solar cell 2, the first electrode 120 of the rightmost solar cell n is not connected to the second electrodes 140 of the other solar cells (1˜(n−1)) and is in an electrically open state. Hereinafter, for convenience of explanation, description will be directed to where the first electrode 120 of the first solar cell 1 is not connected to the second electrodes 140 of the other solar cells (2˜n).

As such, when the first electrode 120 included in the first solar cell 1 is not connected to the second electrodes 140 of the other solar cells (2˜n) and forms the open circuit, the first solar cell 1 is a dead cell that cannot generate electricity.

Therefore, the first solar cell 1 may be provided with a smaller width. That is, when the first solar cell 1 has a width smaller than widths of the other solar cells (2˜n) except for the first solar cell 1, an area of the other solar cells (2˜n) except for the first solar cell 1 may increase. Accordingly, overall efficiency of the thin-film solar cell module 100 may be enhanced. To achieve this, the first electrode 120 included in the first solar cell 1 may have a width smaller than widths of the first electrodes 120 of the other solar cells (2˜n).

Meanwhile, the first electrode 120 included in the first solar cell 1 is not connected to an external electrode terminal, and thus, current does not flow through the first electrode 120 included in the first solar cell 1. Therefore, even in the case where the first electrode 120 of the first solar cell 1 is connected to the first electrode 120 of the second solar cell 2, it does not affect the operation of the thin-film solar cell module 100, and the first electrode 120 of the first solar cell 1 has a voltage that is same as that of the first electrode 120 of the second solar cell 2. Accordingly, a leftmost first groove 125a for separating the first electrodes 120 of the first and second solar cells 1 and 2 may be omitted.

The photoelectric conversion layer 130 may include a p-type semiconductor film, an n-type semiconductor film, and an n-type semiconductor film to form a P-N junction. Each of the semiconductor films may include amorphous silicon, microcrystalline or nanocrystalline silicon, or crystalline silicon.

In addition, the photoelectric conversion layer 130 may be a tandem type or triple type where a plurality of the p-i-n semiconductor films are stacked on each other. Here, an intermediate layer may be formed between one p-i-n semiconductor films and another p-i-n semiconductor films.

The photoelectric conversion layers 130 may be separated from each other by second grooves 135. The second grooves 135 are formed at portions different from the portions where the first grooves 125 are formed. The second grooves 135 extend to upper surfaces of the first electrodes 120. Also, the second electrode 140 on the photoelectric conversion layer 130 extends into the second grooves 135, and thus, the first electrode 120 and the second electrode 140 are directly connected to each other.

The second electrode 140 may include a metal having a high electrical conductivity, such as gold (Au), silver (Ag), aluminum (Al), and the like. The second electrodes 140 may be separated from each other by third grooves 145. The third grooves 145 are formed at portions different from the positions where the first and second grooves 125 and 135 are formed. The third grooves 145 extend to the upper surfaces of the first electrodes 120. Thereby, the plurality of solar cells (1˜n) are formed. The plurality of solar cells (1˜n) are connected in series because a space exists in the third grooves 145. A fourth groove 160 may be formed outside the first solar cell 1 and the other outermost solar cell n. The fourth groove 160 may be entirely formed at a periphery of the thin-film solar cell module 100, and extends to an upper surface of the substrate 110. The plurality of solar cells (1˜n) are isolated or insulated from the external factors because the space exists in the fourth grooves 160.

Meanwhile, when the solar light is absorbed into the i-type semiconductor film, the process of generating the electricity from the thin-film solar cell module 100 starts. That is, when the incident light has an optical band gap larger than that of the amorphous silicon, the microcrystalline or nanocrystalline silicon, or the crystalline silicon, the electron is excited, thereby generating electron-hole pairs. The generated electrons and holes moves to the n-type semiconductor film and the p-type electrodes by an internal field, respectively.

Also, a first electrode terminal 152 is formed on the first solar cell 1, and a second electrode terminal 154 is formed on the other outermost cell n (that is, the rightmost cell opposite to the first solar cell 1) among the plurality of solar cells (1˜n). Thus, the electrons and the holes generated from the photoelectric conversion layers 130 of the plurality of solar cells (1˜n) connected to each other in series are collected through the first electrode terminal 152 and the second electrode terminal 154, and are delivered to the outside.

Meanwhile, as in the above, when the first electrode 120 of the first solar cell 1 forms the open circuit, the first solar cell 1 becomes the dead cell where the electrons and the holes generated from the photoelectric conversion layer 130 cannot be delivered to the outside.

As in the above, the first solar cell 1, which is the dead cell, may be have a width smaller than that of the other solar cells (2˜n) except for the first solar cell 1.

To achieve this, as shown in FIG. 3(a), one first groove 125a of the first grooves 125 between the first electrodes 120 of the first and second solar cells 1 and 2 may overlap one second groove 135a of the second grooves 135 between the photoelectric conversion layers 130 of the first and second solar cells 1 and 2. Thereby, the area of the other solar cells (2˜n) may be relatively increased.

However, the other solar cells (2˜n) generating the electricity are connected to each other in series. Thus, when the output of one solar cell is different from the output of another solar cell, the overall current is adjusted corresponding to the current of the lower output. Accordingly, the photoelectric conversion layers 130 of the other solar cells (2˜n) may have substantially the same widths to each other.

As such, it is preferable that the first solar cell 1, which is the dead cell, has the small width. However, with reference to FIG. 3(b), the first solar cell 1 may have the width D1 that is larger than the width D2 of the first electrode terminal 152 by about 0.1˜4 mm, considering that the first electrode terminal 152 is formed on the first solar cell 1.

If the difference between the width D1 of the first solar cell 1 and the width D2 of the first electrode terminal 152 is smaller than about 0.1 mm, a short circuit may be induced between adjacent first and second solar cells 1 and 2. Also, it is possible that the first electrode terminal 152 is not accurately positioned due to process errors.

On the other hand, if the difference between the width D1 of the first solar cell 1 and the width D2 of the first electrode terminal 152 is larger than about 4 mm, then the first solar cell 1, which is the dead cell, has a relatively large area. Thus, the efficiency of the thin-film solar cell module 100 may be reduced.

Referring to FIG. 2 again, a sealing layer 180 may be formed on the plurality of solar cells (1˜n) in order to seal the plurality of solar cells (1˜n). The sealing layer 180 may include an insulating resin for coating and sealing the entire surface of the substrate 110. Surfaces of the first and second electrode terminals 152 and 154 may be exposed through the sealing layer 180 for connecting the first and second electrode terminals 152 and 154 to the outside.

FIGS. 4 to 8 are cross-sectional views illustrating a method for manufacturing a thin-film solar cell module according to an embodiment of the present invention.

A method for manufacturing a thin-film solar cell module 100 will be described with reference to FIGS. 4 to 8. First, as shown in FIG. 4, a transparent conductive layer is deposited on an entire surface of a substrate 110 and is patterned.

The transparent conductive layer may be formed by a deposition method such as sputtering or by a plating method. The transparent conductive layer may be formed of one material selected from the group including tin oxide (SnO₂), zinc oxide (ZnO), and indium tin oxide (ITO), or a metal oxide including at least one impurity.

The patterning of the transparent conductive layer may be performed by a P1 scribing process. The P1 scribing process is for forming first grooves 125. In the P1 scribing process, a laser is irradiated to the substrate 110 from the lower portion of the substrate 110, and a part of the transparent conductive layer is evaporated or eliminated. Thus, first electrodes 120 are spaced from each other with uniform distances by the first grooves 125.

Meanwhile, as described in the above with reference to FIGS. 1 and 2, in order to reduce the width of the first solar cell 1, the first electrode 120a of the first solar cell 1 may have a width smaller than widths of the first electrodes 120 included in other solar cells (2˜n). Also, since current does not flow through the first electrode 120a included in the first solar cell 1, a leftmost first groove 125a for separating the first electrodes 120 of the first and second solar cells 1 and 2 may be omitted.

Next, as shown in FIG. 5, photoelectric conversion layers 130 are formed on the first electrode 120.

The photoelectric conversion layer 130 may be formed by successively stacking a p-type semiconductor film, an i-type semiconductor film, and an n-type semiconductor film. Each of the semiconductor films may include amorphous silicon, microcrystalline or nanocrystalline silicon, or crystalline silicon.

In addition, the photoelectric conversion layer 130 may be a tandem type or triple type where a plurality of the p-i-n semiconductor films are stacked on each other. Here, an intermediate layer may be formed between one p-i-n semiconductor films and another p-i-n semiconductor films. Here, the intermediate layer may include a TCO-based material or a silicon oxide (SiOx). Specifically, because the silicon oxide includes the silicon constituting the photoelectric conversion layer 130, to use the silicon oxide improves the adhesive property between the stacked p-i-n semiconductor films.

The photoelectric conversion layer 130 may be formed by a plasma-enhanced chemical vapor deposition (PECVD) method, and the like, and may be patterned by a P2 scribing process.

The P2 scribing process is the same as the P1 scribing process. However, the laser power used for the P2 scribing process is smaller than that used for the P1 scribing process. Thus, when a laser is irradiated to the substrate 110 from the lower portion of the substrate 110, the first electrode 120 is not evaporated, and only a part of the photoelectric conversion layer 130 on the first electrode 120 is selectively evaporated and eliminated. Second grooves 135 are formed by the P2 the scribing process, and the photoelectric conversion layer 130 is divided into the plurality of photoelectric conversion layers 130 by the second grooves 135.

To reduce the width of the first solar cell 1, as in the above, one first groove 125a of the first grooves 125 between the first electrodes 120a and 120b of the first and second solar cells 1 and 2 may overlap one second groove 135a of the second grooves 135 between the photoelectric conversion layers 130 of the first and second solar cells 1 and 2. Thereby, the area of the other solar cells (2˜n) may be relatively increased. Thereby, the photoelectric conversion layer 130 of the first solar cell 1, which is a dead cell, may have a width smaller than the widths of the other solar cells (2˜n). Thus, the efficiency of the thin-film solar cell module 100 may be enhanced.

Next, as shown in FIG. 6, the second electrodes 140 are formed on the photoelectric conversion layer 130.

The second electrodes 140 may be formed by forming an electrode layer using a conductive metal material and patterning the same. Meanwhile, the second electrodes 140 may include various materials according to manufacturing methods.

For example, when the second electrodes 140 are formed by a screen method, a material selected from silver (Ag), aluminum (Al), or the combination thereof may be used. Selectively, when the second electrodes 140 are formed by an inkjet method or a dispensing method, a material selected from nickel (Ni), silver (Ag), or the combination thereof may be used.

Also, when the second electrodes 140 are formed by a plating method, a material selected from nickel (Ni), copper (Cu), silver (Ag), or the combination thereof may be used. When the second electrodes 140 are formed by a deposition method, a material selected from aluminum (Al), nickel (Ni), copper (Cu), silver (Ag), titanium (Ti) or the combination thereof may be used.

In addition, when the second electrodes 140 are formed by the screen method, a compound of silver (Ag) and a conductive polymer may be used.

The second electrode 140 may fill the inside of the second grooves 135, and may be directly connected to the first electrode 120.

Meanwhile, the second electrodes 140 are divided by third grooves 145. The third grooves 145 are formed by a P3 scribing process, and extend to an upper surface of the first electrode 120. Space exists inside the third grooves 145, and the third grooves 145 form an insulating layer. Thus, the plurality of solar cells (1˜n) may be connected to each other in series by the third grooves 145.

Here, as in the above, the first electrode 120a included in the first solar cell 1 forms the open circuit. Thus, the first solar cell 1 may preferably have a width smaller than widths of the other solar cells (2˜n).

Next, as shown in FIG. 7, a fourth groove 160 for insulating or isolating the plurality of solar cells (1˜n) is formed. The fourth groove 160 is formed by a P4 scribing process. The upper surface of the substrate 110 is exposed by the fourth groove 160.

Finally, a first electrode terminal 152 is formed on the first solar cell 1, and a second electrode terminal 154 is formed on an other outermost solar cell 1 (that is, the rightmost cell opposite to the first solar cell 1). And then, a sealing layer 180 including an insulating resin is formed on the substrate 110 for covering and sealing the entire surface of the substrate 110.

Here, the first electrode terminal 152 and the second electrode terminal 154 are exposed to the outside through the sealing layer 180. Also, the first solar cell 1 may preferably have the width larger than the width of the first electrode terminal 152 by about 0.1˜4 mm.

By reducing a width of the outermost solar cell (that is a dead cell), the conversion efficiency of the thin-film solar cell may be enhanced.

Certain embodiments of the invention have been described. However, the invention is not limited to the specific embodiments described above; and various modifications of the embodiments are possible by those skilled in the art to which the invention belongs without leaving the scope defined by the appended claims.

What is claimed is:

1. A thin-film solar cell module, comprising:
a transparent substrate; and
a plurality of solar cells formed on the transparent substrate, wherein the plurality of solar cells being in parallel to each other and being connected to each other in series,
wherein each of the plurality of solar cells comprises a first electrode on the transparent substrate, a photoelectric conversion layer on the first electrode, and the second electrode on the photoelectric conversion layer,
the plurality of solar cells comprise a first solar cell that is an outermost solar cell,
the first electrode of the first solar cell is electrically open, and
the first electrode of the first solar cell has a width smaller than widths of the first electrodes of the plurality of solar cells other than the first solar cell.

2. The thin-film solar cell module according to claim 1, wherein the first solar cell has a width smaller than widths of the plurality of solar cells other than the first solar cell.

3. The thin-film solar cell module according to claim 2, wherein the plurality of solar cells other than the first solar cell have substantially same widths with respect to each other.

4. The thin-film solar cell module according to claim 2, further comprising a first electrode terminal on the first solar cell and a second electrode terminal on an other outermost solar cell among the plurality of solar cells,
wherein the first solar cell has the width larger than a width of the first electrode terminal by about 0.1˜4 mm.

5. The thin-film solar cell module according to claim 1, wherein the plurality of solar cells comprise one solar cell and an adjacent solar cell,
the first electrode of the one solar cell is separated from the first electrode of the adjacent solar cell by a first groove,
the photoelectric conversion layer of the one solar cell is separated from the photoelectric conversion layer of the adjacent solar cell by a second groove, and
the first groove is at a different position with respect to the second groove.

6. The thin-film solar cell module according to claim 1, wherein the plurality of solar cells comprise a second solar cell that is adjacent to the first solar cell,
the first electrode of the first solar cell is separated from the first electrode of the second solar cell by a first groove,
the photoelectric conversion layer of the first solar cell is separated from the photoelectric conversion layer of the second solar cell by a second groove, and
the first groove and the second groove partially overlap with each other.

7. The thin film solar cell module according to claim 1, wherein the plurality of solar cells connected to each other in series comprise the first electrode of one solar cell being separated from the first electrode of an adjacent solar cell by a first groove, the photoelectric conversion layer of the one solar cell being separated from the photoelectric conversion layer of the adjacent solar cell by a second groove, the second groove extending to an upper surface of the first electrode of the adjacent solar cell, the second electrode of the one solar cell extending into the second groove to connect to the first electrode of the adjacent solar cell, and the second electrode of the one solar cell being separated from the second electrode of the adjacent solar cell by a third groove, and the third groove extending to an upper surface of the first electrode of the adjacent solar cell.

8. The thin solar cell module according to claim 1, wherein a groove is formed in a material at a periphery of the plurality of solar cells and extends to an upper surface of the transparent substrate.

9. The thin-film solar cell module according to claim 1, further comprising:
a sealing layer for sealing the plurality of solar cells.

10. The thin-film solar cell module according to claim 1, wherein the plurality of solar cells comprise a second solar cell that is adjacent to the first solar cell, and
the first electrode of the first solar cell is connected to the first electrode of the second solar cell.

11. A method for manufacturing a thin-film solar cell module, comprising steps of:
forming first electrodes spaced from each other by depositing a conductive layer on a transparent substrate and patterning the conductive layer;
forming photoelectric conversion layers spaced from each other by depositing a silicon thin-film layer on the first electrodes and patterning the silicon thin-film layer; and
forming a plurality of solar cells by depositing an electrode layer on the photoelectric conversion layers and patterning the electrode layer to form second electrodes, wherein the plurality of solar cells are arranged in parallel to each other, each of the plurality of solar cells comprising the first electrode, the second electrode, and the photoelectric conversion layers,
wherein the plurality of solar cells comprise a first solar cell that is an outermost solar cell,
the first electrode of the first solar cell is electrically open, and
the first electrode of the first solar cell has a width smaller than widths of the first electrodes of the plurality of solar cells other than the first solar cell.

12. The method according to claim 11, wherein the first solar cell has a width smaller than widths of the plurality of solar cells other than the first solar cell.

13. The method according to claim 12, wherein the plurality of solar cells comprise a second solar cell that is adjacent to the first solar cell, and
the method further comprises a step of forming a first electrode terminal on the first solar cell and a second electrode terminal on an other outermost solar cell among the plurality of solar cells.

14. The method according to claim 13, wherein the first solar cell has the width larger than a width of the first electrode terminal by about 0.1˜4 mm.

15. The method according to claim 11, wherein the plurality of solar cells comprise one solar cell and an adjacent cell,
in the step of forming the first electrodes, first grooves are formed through a first scribing process to separate the first electrodes,
in the step of forming the photoelectric conversion layers, second grooves are formed through a second scribing process to separate the photoelectric conversion layers, wherein at least one first groove is at a different position with respect to at least one second groove.

16. The method according to claim 11, wherein the plurality of solar cells comprise a second solar cell that is adjacent to the first solar cell, and the method comprises omitting forming the patterning of the conductive layer between the first solar cell and the second solar cell such that the first electrode of the first solar cell is connected to the first electrode of the second solar cell.

17. The method according to claim 11, wherein the plurality of solar cells comprise a second solar cell that is adjacent to the first solar cell,
in the step of forming the first electrodes, first grooves are formed through a first scribing process to separate the first electrodes,
in the step of forming the photoelectric conversion layers, second groove are formed through a second scribing process to separate the photoelectric conversion layers, and
one first groove of the first grooves between the first electrodes of the first solar cell and the second solar cell partially overlaps one second groove of the second grooves between the photoelectric conversion layers of the first solar cell and the second solar cell.

18. The method according to claim 11, further comprising a step of:
forming a sealing layer for sealing the plurality of solar cells.

19. The method according to claim 11, wherein the plurality of solar cells comprise one solar cell and an adjacent cell,
in the step of forming the first electrodes, first grooves are formed through a first scribing process to separate the first electrodes,
in the step of forming the photoelectric conversion layers, second grooves are formed through a second scribing process to separate the photoelectric conversion layers, a second groove extending to an upper surface of a first electrode of the adjacent solar cell
in the step of forming the second electrodes, third grooves are formed through a third scribing process to separate the second electrodes, a third groove extending an upper surface of the first electrode of the adjacent solar cell, and a second electrode of the one solar cell extends into the second groove to be connected to the first electrode of the adjacent solar cell.

20. The method according to claim 11 further comprises forming a groove at a periphery of the plurality of solar cells by patterning the conductive layer, the photoelectric conversion layers, and the electrode layer, wherein the groove extends to an upper surface of the transparent substrate.
